(19) United States
(12) Patent Application Publication
(10) Pub. No.: US 2024/0188269 A1
(43) Pub. Date: Jun. 6, 2024

(54) LINEAR HEAD MODULE AND ELECTRONIC COMPONENT MOUNTING APPARATUS

(71) Applicant: KABUSHIKI KAISHA YASKAWA DENKI, Kitakyushu-shi (JP)

(72) Inventors: Naoki ASANUMA, Kitakyushu-shi (JP); Daisuke MIYAZAKI, Kitakyushu-shi (JP); Toshiyuki YAMAGISHI, Kitakyushu-shi (JP); Shinobu ARISAWA, Kitakyushu-shi (JP); Toru TAKANO, Kitakyushu-shi (JP); Toshiaki TSUCHIDA, Kitakyushu-shi (JP); Shinichi KIMURA, Kitakyushu-shi (JP); Mitsuru IWAKIRI, Kitakyushu-shi (JP); Yoshiki NAGANO, Kitakyushu-shi (JP)

(73) Assignee: KABUSHIKI KAISHA YASKAWA DENKI, Kitakyushu-shi (JP)

(21) Appl. No.: 18/525,869

(22) Filed: Dec. 1, 2023

(30) Foreign Application Priority Data
Dec. 5, 2022 (JP) 2022-194486
Nov. 13, 2023 (JP) 2023-193239

(51) Int. Cl. H05K 13/04; H02K 9/18; H02K 9/26; H02K 11/21; H02K 41/03

(52) U.S. Cl. CPC H05K 13/04; H02K 9/18; H02K 9/26; H02K 11/21; H02K 41/031

(57) ABSTRACT

A linear head module includes linear motors each of which includes a movable element and a stator. The movable element includes a shaft having a shaft axis, and magnets fixed to the shaft. The stator includes a coil and a back yoke having a back yoke axis. The movable element is inserted into the back yoke movably along the shaft axis such that the shaft axis substantially coincides with the back yoke axis. The back yoke includes a protruding portion protruding outwardly. The coil is fixed to the back yoke to face the magnets. The linear motors are arranged such that the protruding portion of a first linear motor among the linear motors protrudes along a first protruding direction different from a second protruding direction along which the protruding portion of a second linear motor among the linear motors protrudes.

### CROSS-REFERENCE TO RELATED APPLICATIONS

The present application claims priority under 35 U. S. C. § 119 to Japanese Patent Application No. 2022-194486, filed Dec. 5, 2022 and Japanese Patent Application No. 2023-193239, filed Nov. 13, 2023. The contents of these applications are incorporated herein by reference in their entirety.

### BACKGROUND OF THE INVENTION

### Field of the Invention

Embodiments of the disclosure relate to a linear head module and an electronic component mounting apparatus.

### Discussion of the Background

Japanese Patent No. 4385406 discloses a linear head module provided with a plurality of heads for performing linear motion. In the linear head module, each head is constituted by a linear motor. A linear motor includes a pipe, a coil fixed to the inner surface of the pipe, a magnet mounted to an output shaft slidably disposed in the pipe in the axial direction so as to face the coil in the radial direction with a gap therebetween, and a linear motion guide for supporting the output shaft.

### SUMMARY OF THE INVENTION

According to one aspect of the present invention, a linear head module includes a plurality of linear motors. Each of the plurality of linear motors includes a movable element and a stator. The movable element includes a shaft having a shaft axis and an outer peripheral surface around the shaft axis, and a plurality of magnets fixed to the outer peripheral surface of the shaft. The stator includes a back yoke and a coil. The back yoke has a back yoke axis and an inner peripheral surface around the back yoke axis. The movable element is inserted into the back yoke to be movable along the shaft axis such that the shaft axis substantially coincides with the back yoke axis. The back yoke includes a protruding portion that protrudes outwardly and that extends along the back yoke axis. The coil is fixed to the inner peripheral surface of the back yoke to face the plurality of magnets with a gap between the coil and the plurality of magnets. The plurality of linear motors is arranged in a lattice shape such that the shaft axis of each of the plurality of linear motors is substantially parallel each other. The plurality of linear motors is arranged such that the protruding portion of a first linear motor among the plurality of linear motors protrudes along a first protruding direction different from a second protruding direction along which the protruding portion of a second linear motor among the plurality of linear motors protrudes.

According to another aspect of the present invention, an electronic component mounting apparatus includes the linear head module described above, a transport mechanism configured to transfer a substrate, and a moving mechanism configured to move the linear head module with respect to the substrate. The linear head module stands on a base.

### BRIEF DESCRIPTION OF THE DRAWINGS

A more complete appreciation of the present disclosure and many of the attendant advantages thereof will be readily obtained as the same becomes better understood by reference to the following detailed description when considered in connection with the accompanying drawings.

FIG. 1 is a top view showing an example of the overall configuration of an electronic component mounting apparatus.

FIG. 2 is a perspective view showing an example of the overall configuration of the linear head module.

FIG. 3 is a perspective view showing an example of the overall configuration of the linear head module which transparently illustrates a part of the linear motor.

FIG. 4 is a bottom view showing an example of the overall configuration of the linear head module.

FIG. 5 is a side view showing an example of the overall configuration of the linear head module.

FIG. 6 is a top view showing an example of the overall configuration of the linear head module.

FIG. 7 is a cross-sectional view showing an example of an arrangement direction of a plurality of linear motors.

FIG. 8 is an explanatory diagram showing an example of fan arrangement and air flow.

FIG. 9 is an explanatory diagram showing an example of a method for determining the dimensions of each component constituting the linear motor.

FIG. 10 is an explanatory view showing an example of a method for determining the dimensions of each component constituting the linear motor.

FIG. 11 is a sectional view showing an example of a layered structure of a stator of a linear motor.

FIG. 12 is a side sectional view showing an example of the overall configuration of the linear head module.

### DESCRIPTION OF THE EMBODIMENTS

Embodiments will be described below with reference to the drawings.

### Overall Configuration of Electronic Component Mounting Apparatus

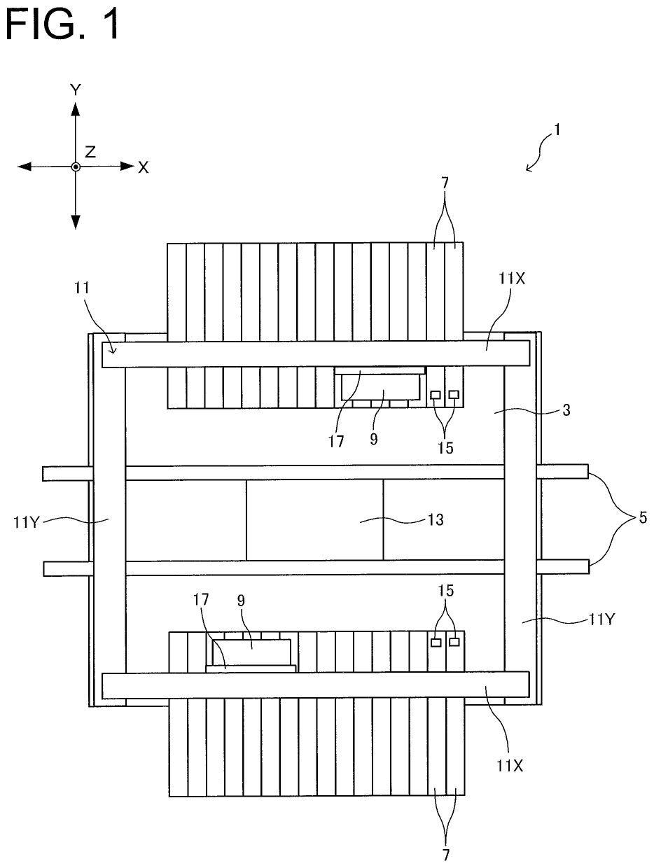

An example of the overall configuration of the electronic component mounting apparatus according to the embodiment will be described with reference to FIG. 1.

As shown in FIG. 1, the electronic component mounting apparatus 1 includes a mount 3, a transport mechanism 5, a parts feeder 7, a linear head module 9, and a moving mechanism 11. The mount 3 constitutes a base of the electronic component mounting apparatus 1. The transport mechanism 5 is installed on the mount 3 to transfer the substrate 13 in the X-axis direction and to stop and hold the substrate 13 at a predetermined position. In this embodiment, the transport direction of the substrate 13 is defined as an X-axis direction, a direction orthogonal to the X-axis direction in a horizontal plane is defined as a Y-axis direction, and a vertical direction orthogonal to the X-axis direction and the Y-axis direction is defined as a Z-axis direction. The X-axis direction is an example of the second direction, the Y-axis direction is an example of the first direction, and the Z-axis direction is an example of the axial direction along a shaft axis of a shaft 37.

A plurality of parts feeders 7 is provided on both sides of the transport mechanism 5 in the Y-axis direction. The parts feeders 7 sequentially supply a plurality of electronic components to the supply port 15. The linear head module 9 adsorbs and holds the electronic component supplied to the supply port 15, transports the electronic component to a corresponding position on the substrate 13, and attaches the electronic component to the substrate 13.

The moving mechanism 11 moves the linear head module 9 standing on the base 17 in the X-axis direction and the Y-axis direction with respect to the substrate 13. The moving mechanism 11 has a pair of X-axis tables 11X and a pair of Y-axis tables 11Y The Y-axis tables 11Y are mounted on the mount 3, the X-axis tables 11X are bridged by a pair of Y-axis tables 11Y, and the linear head module 9 is mounted on each of the pair of X-axis tables 11X. The X-axis tables 11X move the linear head module 9 in the X-axis direction, and the Y-axis tables 11Y move the X-axis table 11X, that is, the linear head module 9 in the Y-axis direction.

It should be noted that the above-described configuration of the electronic component mounting apparatus 1 is merely an example, and a configuration other than the above-described configuration may be adopted.

### Overall Configuration of Linear Head Module

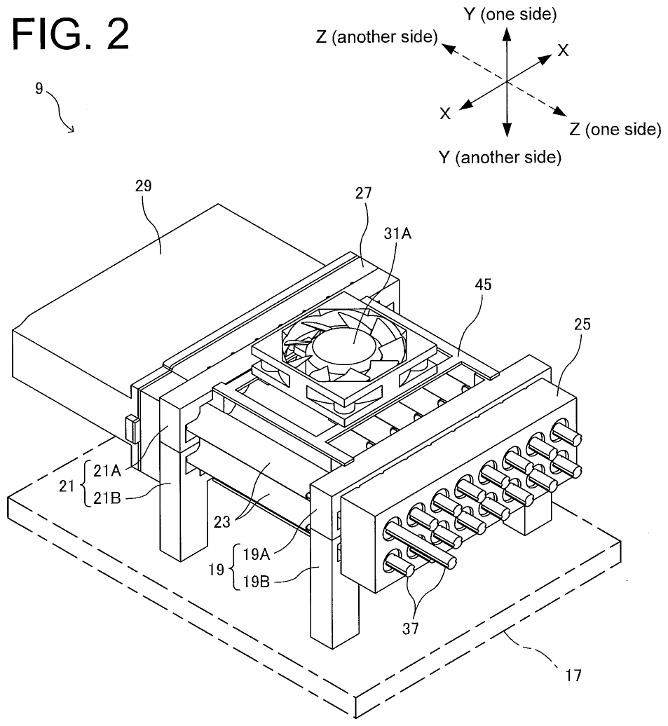

An example of the overall configuration of the linear head module 9 will be described with reference to FIGS. 2 to 6. The directions of the X-axis, the Y-axis, and the Z-axis in FIGS. 2 to 6 respectively correspond to the directions in FIG. 1.

As shown in FIGS. 2 to 6, the linear head module 9 includes a first frame 19, a second frame 21, a plurality of linear motors 23, a first linear motion guide portion 25, a second linear motion guide portion 27, a linear encoder 29, and fans 31A and 31B.

The first frame 19 is erected on the base 17 of the electronic component mounting apparatus 1 and supports one side of the plurality of linear motors 23 in the Z-axis direction. The first frame 19 can be divided into a top frame 19A on one side in the Y-axis direction and a bottom frame 19B on the another side in the Y-axis direction.

The second frame 21 is erected on the base 17 of the electronic component mounting apparatus 1 and is spaced apart from the first frame 19 in the Z-axis direction. The second frame 21 supports the another side in the Z-axis direction of the plurality of linear motors 23. The second frame 21 can be divided into a top frame 21A on one side in the Y-axis direction and a bottom frame 21B on the another side in the Y-axis direction.

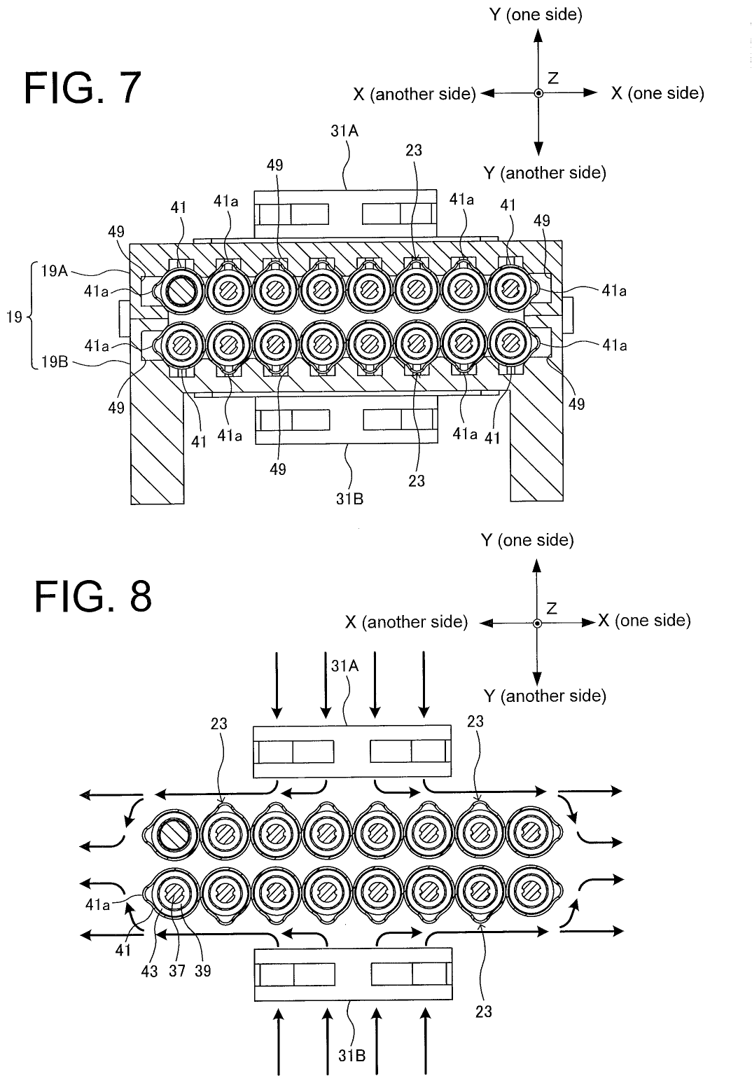

The plurality of linear motors 23 is supported by a first frame 19 and a second frame 21 in such a state that they are arranged adjacent to each other in a lattice shape when viewed from the Z-axis direction. In the present embodiment, as shown in FIG. 7, which will be described later, the number of linear motors 23 is, for example, 16, the number of columns in the Y-axis direction is 2 (an example of a first number), and the number of columns in the X-axis direction is 8 (an example of a second number), which is more than 2. The number and arrangement of the linear motors 23 may be different from those described above.

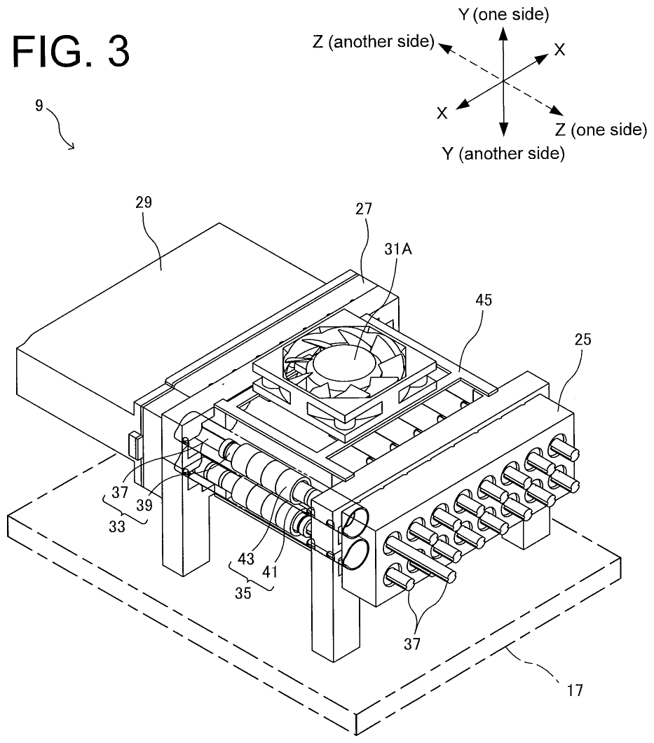

FIG. 3 shows the internal structure of part of the linear motor 23 in a transparent manner. As shown in FIG. 3, each of the plurality of linear motors 23 has a movable element 33 and a stator 35. The movable element 33 has the shaft 37 and a plurality of magnets 39 fixed to the shaft 37 and arranged along the Z-axis direction along the shaft axis of the shaft 37. The stator 35 has a back yoke 41 constituting a cylindrical frame, and a plurality of coils 43 fixed to the inner peripheral surface of the back yoke 41 and arranged to face the radially outer side of the magnet 39 with a gap therebetween. The linear motor 23 moves the movable element 33 in the Z-axis direction with respect to the stator 35, thereby moving the shaft 37 in the Z-axis direction. A nozzle mechanism (not illustrated) capable of absorbing and holding an electronic component is provided at one end of the shaft 37 in the Z-axis direction.

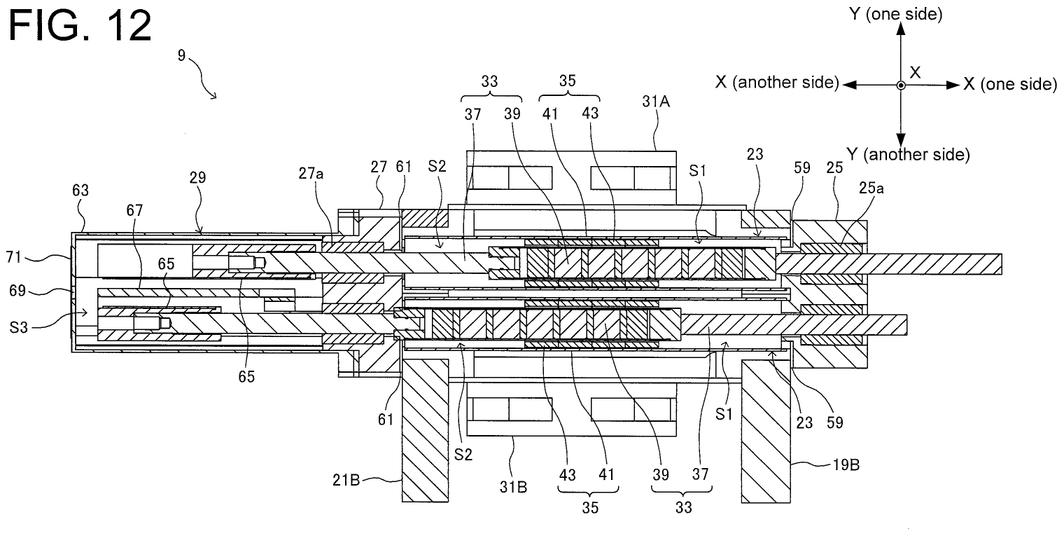

As shown in FIGS. 2, 3, and 5, the first linear motion guide portion 25 is provided on one side of the first frame 19 in the Z-axis direction. As shown in FIG. 12, which will be described later, the first linear motion guide portion 25 includes a first linear motion guide portion 25a for supporting the shafts 37 of the plurality of linear motors 23 so as to be linearly movable in the Z-axis direction. The second linear motion guide portion 27 is provided on the another side of the second frame 21 in the Z-axis direction. As shown in FIG. 12, which will be described later, the second linear motion guide portion 27 includes a second linear motion guide portion 27a that supports the shafts 37 of the plurality of linear motors 23 so as to be linearly movable in the Z-axis direction. The first linear motion guide portion 25a and the second linear motion guide portion 27a are linear bushings for linearly moving the shaft 37 by using rolling of a steel ball, for example.

As shown in FIGS. 2, 3 and 5, the linear encoder 29 is provided on the another side of the second linear motion guide portion 27 in the Z-axis direction. The linear encoder 29 is supported in a cantilever shape by the second frame 21 so as to project to the another side in the Z-axis direction. The linear encoder 29 detects the position of the movable element 33 in each of the plurality of linear motors 23.

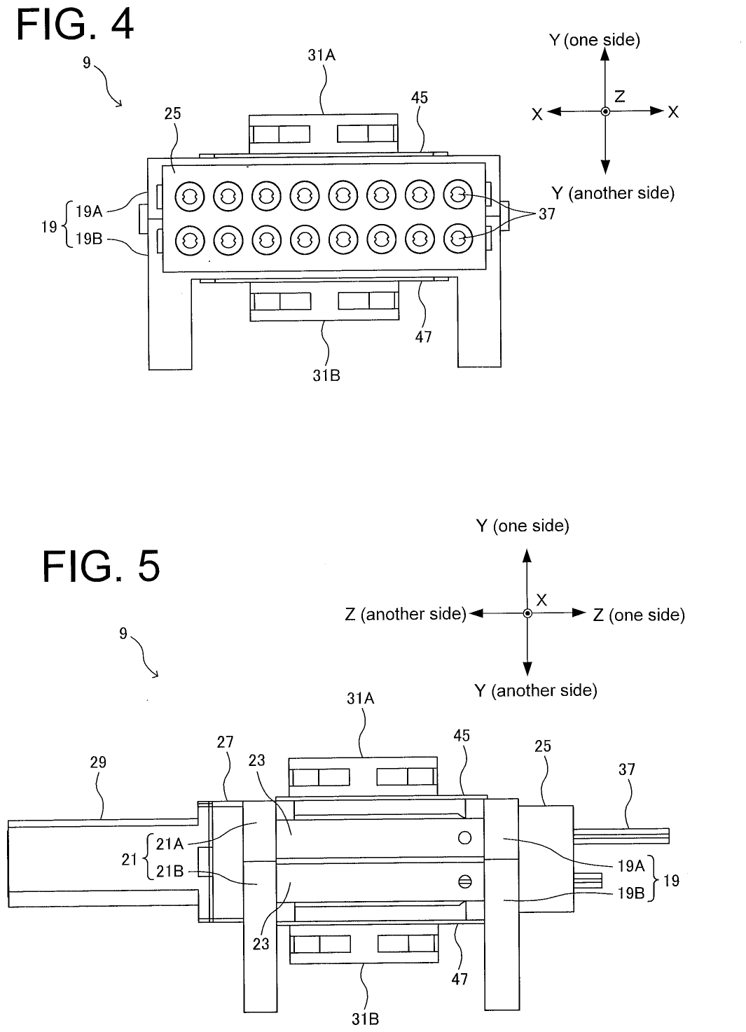

As shown in FIGS. 4 to 6, the linear head module 9 is provided with two fans 31A and 31B. The fan 31A (an example of the first fan) is disposed on one side in the Y-axis direction of the plurality of linear motors 23 by a support member 45. The fan 31A blows air from one side in the Y-axis direction to the plurality of linear motors 23 to cool the linear motors 23. The fan 31B (an example of the second fan) is disposed on the another side in the Y-axis direction of the plurality of linear motors 23 by the support member 47. The fan 31B blows air from the another side in the Y-axis direction to the plurality of linear motors 23 to cool them.

### 3. Arrangement Direction of Linear Motors

An example of the arrangement direction of the plurality of linear motors 23 will be described with reference to FIG. 7. As shown in FIG. 7, the back yoke 41 of each linear motor 23 is provided with a protruding portion 41a through which a crossover wire (not illustrated) of the coil 43 is inserted. The protruding portion 41a bulges radially outer side from the cylindrical surface of the back yoke 41 and extends in the Z-axis direction. The plurality of linear motors 23 is arranged such that the directions of the protruding portion 41a of each linear motor 23 are partially different from each other. In the present embodiment, as shown in FIG. 7, for example, 16 linear motors 23 are arranged adjacent to each other in a lattice shape so that the number of columns in the Y-axis direction is two and the number of columns in the X-axis direction is eight. The sixteen linear motors 23 are arranged such that the protruding portions 41a of the back yoke 41 of the linear motors 23 at both ends in the X-axis direction face outward in the X-axis direction, and the protruding portions 41a of the back yoke 41 of the linear motors 23 other than both ends in the X-axis direction face outward in the Y-axis direction. Specifically, the two linear motors 23 arranged at one end portion in the X-axis direction are arranged so that the protruding portion 41a faces one side in the X-axis direction, and the two linear motors 23 arranged at the another end portion in the X-axis direction are arranged so that the protruding portion 41a faces the another side in the X-axis direction. Among the eight linear motors 23 arranged on one side in the Y-axis direction, six linear motors 23 arranged at positions other than both ends in the X-axis direction are arranged so that the protruding portion 41a face one side in the Y-axis direction. Among the eight linear motors 23 arranged on the another side in the Y-axis direction, six linear motors 23 arranged at positions other than both ends in the X-axis direction are arranged so that the protruding portion 41a face the another side in the Y-axis direction.

Note that “facing one side in the X-axis direction” does not necessarily need to be parallel to the X-axis direction, and may be a direction inclined to one side in the X-axis direction with respect to the Y-axis direction. Similarly, “facing the another side in the X-axis direction” does not necessarily need to be parallel to the X-axis direction, but may be a direction inclined to the another side in the X-axis direction with respect to the Y-axis direction. Similarly, “facing one side in the Y-axis direction” does not necessarily need to be parallel to the Y-axis direction, but may be a direction inclined to one side in the Y-axis direction with respect to the X-axis direction. Similarly, “facing the another side in the Y-axis direction” does not necessarily need to be parallel to the Y-axis direction, but may be a direction inclined to the another side in the Y-axis direction with respect to the X-axis direction.

In the example shown in FIG. 7, eight linear motors 23 arranged on one side in the Y-axis direction are in contact with each other in the X-axis direction, and eight linear motors 23 arranged on the another side in the Y-axis direction are in contact with each other in the X-axis direction, and the eight linear motors 23 on one side in the Y-axis direction and the eight linear motors 23 on the another side in the Y-axis direction are adjacent to each other with a slight gap therebetween. In addition, it is also possible to arrange so that eight units on one side of the Y-axis direction and eight units on the another side of the Y-axis direction abut each other. Further, each linear motor 23 may be disposed with a slight gap therebetween.

Recesses 49 are formed in the top frame 19A and the bottom frame 19B of the first frame 19 at positions corresponding to the protruding portion 41a of the linear motors 23. Each linear motor 23 is positioned by fitting the protruding portion 41a of each linear motor 23 into the recess 49. Since each linear motor 23 can be installed in a state in which the top frame 19A and the bottom frame 19B are divided, workability can be improved. Although not illustrated, the top frame 21A and the bottom frame 21B of the second frame 21 are also configured in the same manner as described above.

With the above configuration, compared to the case where the linear motor 23 is arranged such that the protruding portion 41a of all the back yokes 41 face outward in the Y-axis direction, for example, the protruding portion 41a facing outward in the X-axis direction function as a rib, whereby the strength and vibration resistance of the linear head module 9 can be improved.

### 4. Fan Arrangement and Air Flow

When a plurality of linear motors 23 is arranged adjacent to each other in a lattice shape such as eight columns in the X-axis direction and two columns in the Y-axis direction, for example, as in the linear head module 9, heat of the linear motors 23 near the center in the X-axis direction tends to be trapped because the number of parallel lines in the X-axis direction is relatively large. In this case, for example, even if a fan is disposed on one side or the another side in the X-axis direction and air is blown in the X-axis direction, the heat radiation efficiency of the linear motor 23 near the center in the X-axis direction is poor and the linear motor 23 tends to become hot. In particular, when the gap between the linear motors 23 in the Y-axis direction is narrowed or brought into contact with each other in order to reduce the size of the linear head module 9 in the Y-axis direction, there is a possibility that the flow path of air in the X-axis direction is narrowed or cooling efficiency may be further reduced.

Therefore, in the present embodiment, as shown in FIG. 8, two fans 31A and 31B are disposed on both sides of the plurality of linear motors 23 in the Y-axis direction to blow air. FIG. 8 is an explanatory diagram in which fans 31A and 31B and a plurality of linear motors 23 are extracted, and the flow of air blown by the fans 31A and 31B is represented by arrows. As shown in FIGS. 2 to 6, the fan 31A is disposed on one side in the Y-axis direction of the plurality of linear motors 23 by the support member 45. The fan 31B is disposed on the another side in the Y-axis direction of the plurality of linear motors 23 by a support member 47. Each of the fans 31A and 31B is disposed at a substantially central position in the dimension of the linear head module 9 in the X-axis direction and slightly closer to the another side in the Z-axis direction than the substantially central position in the dimension between the first frame 19 and the second frame 21. The fans 31A and 31B are, for example, axial flow fans.

As shown in FIG. 8, the fan 31A air from one side in the Y-axis direction and discharges it toward the another side. The air discharged from the fan 31A hits the surface of the linear motors 23 arranged in one column in the Y-axis direction among the plurality of linear motors 23, and is blown toward both ends in the X-axis direction. The air that reaches the end portion in the X-axis direction flows outward on one side and the another side in the X-axis direction, and a part of the air flows around the another side in the Y-axis direction along the surface of the linear motor 23 positioned at the end portion in the X-axis direction, and then flows outward on one side and the another side in the X-axis direction. Similarly, the fan 31B air from the another side in the Y-axis direction and discharges it toward the one side. The air discharged from the fan 31B hits the surface of the linear motor 23 arranged in the row on the another side in the Y-axis direction among the plurality of linear motors 23, and is blown toward both ends in the X-axis direction. The air that reaches the end portion in the X-axis direction flows outward on one side and the another side in the X-axis direction, and a part of the air flows around one side in the Y-axis direction along the surface of the linear motor 23 positioned at the end portion in the X-axis direction, and then flows outward on one side and the another side in the X-axis direction.

According to the arrangement of the fans 31A and 31B and the flow of the air described above, the linear motor 23 near the center in the X-axis direction, which is particularly susceptible to heat trapping among the plurality of linear motors 23, can be efficiently cooled. Further, since air can be blown over the entire surface of the plurality of linear motors 23, it is possible to evenly cool the linear motors 23 other than the vicinity of the center in the X-axis direction.

### 5. Dimensions of Each Component Constituting Linear Motor

In the linear head module 9, a plurality of linear motors 23 is arranged adjacent to each other. Therefore, when the motor characteristics are maximized by increasing the amount of magnet input to each linear motor 23, there is a possibility that the adjacent linear motor 23 is affected by the leakage magnetic flux. The influence of the leakage flux is, for example, an increase in friction thrust, cogging thrust, thrust ripple, velocity ripple, and the like. On the other hand, when the amount of the magnet input to each linear motor 23 is reduced, the influence of the magnetic flux leakage to the adjacent linear motor 23 can be reduced, but the motor characteristics are deteriorated. In order to reduce the influence of the leakage magnetic flux while maximizing the motor characteristics, there are coping methods such as increasing the distance between the axes of the adjacent linear motors 23, installing a magnetic shield between the linear motors 23, or increasing the thickness of the back yoke 41.

Therefore, in the present embodiment, by determining the dimensions of each component constituting the linear motor 23 within a predetermined range, the influence of the magnetic flux leakage to the adjacent linear motor 23 can be reduced, and the motor characteristics can be maximized within the specified dimensions.

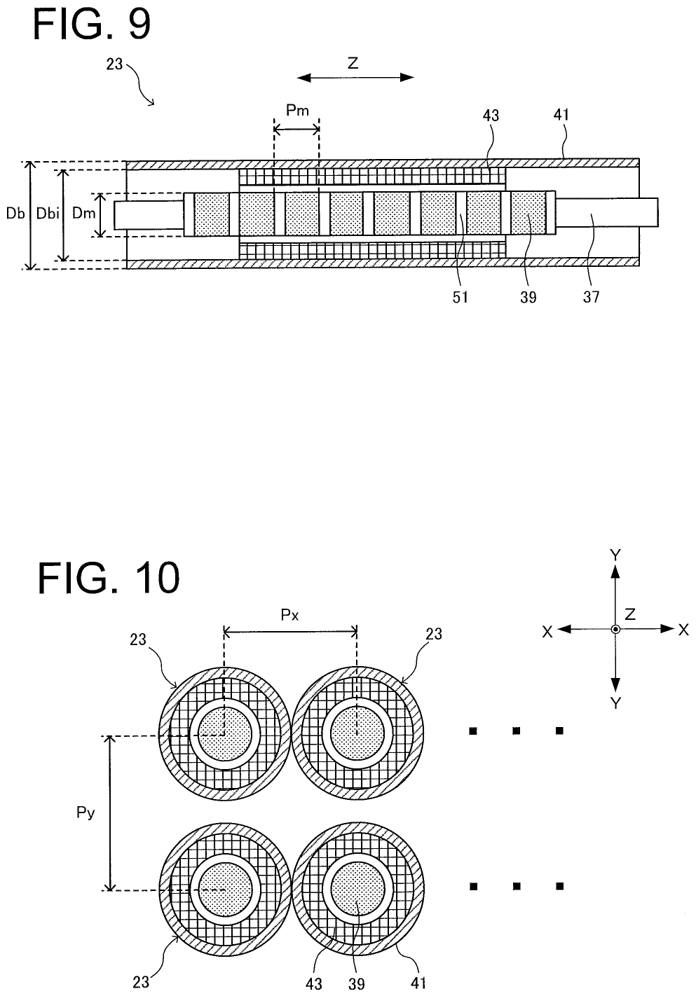

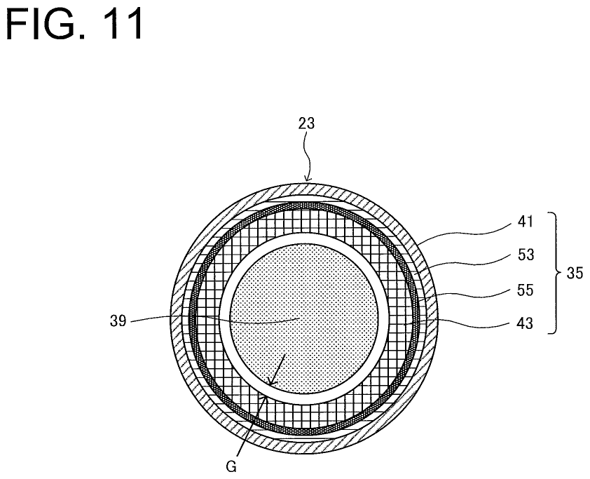

In the linear motor 23, the dimensions of each component are determined so that a design value based on the ratio between the cross-sectional area of the back yoke 41 perpendicular to the Z-axis direction and the cross-sectional area of the magnet 39 perpendicular to the Z-axis direction is within a predetermined numerical range. For example, as shown in FIGS. 9 and 10, when the outer diameter of the back yoke 41 is represented by Db, the inner diameter of the back yoke 41 is represented by Dbi, the outer diameter of the magnet 39 is represented by Dm, the pitch of the magnet 39 in the Z-axis direction is represented by Pm, the minimum distance between axis centers in the X-axis direction or the Y-axis direction, which is a direction perpendicular to the Z-axis direction of an adjacent linear motor 23 is represented by Pmin, and the ratio of the cross-sectional area of the back yoke 41 perpendicular to the Z-axis direction to the cross-sectional area of the magnet 39 perpendicular to the Z-axis direction is represented by Ra. Further, the minimum inter-axial distance Pmin is the smallest inter-axial distance among the inter-axial distance Px between linear motors 23 adjacent in the X-axis direction and the inter-axial distance Py between linear motors 23 adjacent in the Y-axis direction as shown in FIG. 10. For example, in the example shown in FIG. 10, the minimum inter-axial distance Pmin is the inter-axial distance Px. For example, when the back yokes 41 of the adjacent linear motors 23 are arranged so as to be in contact with each other, the outer diameter Db of the back yoke 41 and the minimum distance Pmin between the axes are substantially equal to each other. In this case, for example, the dimensions of each component are determined so that the cross-sectional area of the magnet 39 perpendicular to the Z-axis direction is approximately twice the cross-sectional area of the back yoke 41 perpendicular to the Z-axis direction.

### 6. Layer Structure of Stator of Linear Motor

An example of a layer structure of the stator 35 of the linear motor 23 will be described with reference to FIG. 11. In the drawings other than FIG. 11, the layer structure of the stator 35 is simplified. Further, in FIG. 11, the protruding portion 41a of the back yoke 41 is not shown.

As shown in FIG. 11, the stator 35 includes the back yoke 41, the heat-resistant sheet 53, the foamed sheet 55, and the coil 43. The heat-resistant sheet 53 is made of a material having high heat-resistance and electrical insulating properties, such as polyimide resin, and is provided radially inside the back yoke 41. The foamed sheet 55 is a sheet material which expands in volume by heat treatment, and is provided radially inside the heat-resistant sheet 53. The coil 43 is hardened with varnish, for example, and is provided radially inside the foamed sheet 55. The inner peripheral surface of the coil 43 and the outer peripheral surface of the magnet 39 are arranged to face each other in the radial direction via a gap G. A nonwoven fabric may be provided on the radially inner side of the coil 43.

If the coil of the stator is fixed to the back yoke by casting resin, time is required for defoaming and curing of the resin, resulting in an increase in man-hours. In addition, there is a problem that a manual operation such as checking that the inner peripheral side of the coil is covered with the resin and removing the resin which has overflowed occurs. In the linear motor 23 of the present embodiment, since the foamed sheet 55 is disposed between the inner peripheral surface of the back yoke 41 and the outer peripheral surface of the coil 43 as described above, it is possible to expand the volume of the foamed sheet 55 and fix the coil 43 to the back yoke 41 by heat treatment in a heating furnace, for example. As a result, casting of resin becomes unnecessary, so that man-hours can be greatly reduced, and the above-described manual operation becomes unnecessary.

### 7. Air Release Structure Using Air Hole

In the linear motor, when the movable element moves to one side and the another side in the axial direction with respect to the stator, viscous resistance may be generated due to changes in the internal pressure. When the viscous resistance is generated, there is a possibility that the positioning accuracy of the electronic component is lowered.

Therefore, in the present embodiment, as shown in FIG. 12, a plurality of air holes 59 is formed in the first linear motion guide portion 25 (an example of a first member) disposed on one side in the Z-axis direction of the plurality of linear motors 23. The air hole 59 is formed for each of the plurality of linear motors 23. The air hole 59 communicates the inner space S1 of the back yoke 41 of the linear motor 23 on one side in the Z-axis direction of the stator 35, which is the inner space S1 of the back yoke 41, with the outer space of the back yoke 41. A plurality of air holes 61 is formed in a second linear motion guide portion 27 (an example of a second member) arranged on the another side in the Z-axis direction of the plurality of linear motors 23. The air hole 61 is formed for each of the plurality of linear motors 23. The air hole 61 communicates the inner space S2 of the stator 35 on the another side in the Z-axis direction, which is the inner space S1 of the back yoke 41 of the linear motor 23, with the outer space of the back yoke 41.

According to the above configuration, the change in the internal pressure when the movable element 33 moves to one side and the another side in the Z-axis direction with respect to the stator 35 can be suppressed, so that the occurrence of viscous resistance can be suppressed.

As shown in FIG. 12, the linear encoder 29 includes a case 63, a plurality of linear scales 65, and a plurality of detection units 67. The case 63 is provided on the another side of the second linear motion guide portion 27 in the Z-axis direction, and houses the linear scale 65 and the detection portion 67. The linear scale 65 is provided for each of the plurality of linear motors 23, and is provided at the end of the shaft 37 of each linear motor 23 on the another side in the Z-axis direction. The detection unit 67 is provided for each of the plurality of linear motors 23, and detects the linear scale 65 of each linear motor 23. The plurality of detection units 67 may be mounted at positions corresponding to the respective linear scales 65, for example, on the front and back surfaces of one substrate.

With the above configuration, in the linear encoder 29 as well, when the linear scale 65 of each axis moves to one side and the another side in the Z-axis direction with respect to the detection unit 67, viscous resistance may be generated due to a change in the internal pressure. When the viscous resistance is generated, there is a possibility that the positioning accuracy of the electronic component is lowered.

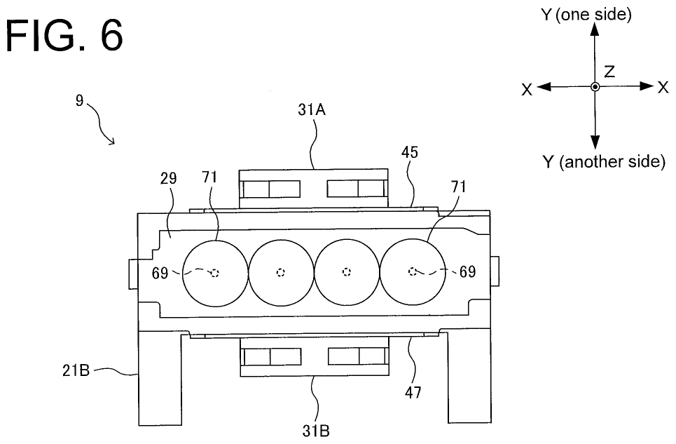

Therefore, in the present embodiment, as shown in FIG. 12, a plurality of air holes 69 is formed in the side surface of the case 63 on the another side in the Z-axis direction. The air hole 69 communicates the inner space S3 of the case 63 with the outer space. The number of the air holes 69 is not particularly limited, but in this embodiment, for example, four air holes 69 are provided at equal intervals along the X-axis direction (see FIG. 6). Further, an air filter 71 is provided in each air hole 69. The air filter 71 has an area larger than the opening area of the air hole 69, and is provided on the side surface of the case 63 so as to cover the air hole 69. Although the number of the air filters 71 is not particularly limited, in the present embodiment, four circular air filters 71 are provided at equal intervals along the X-axis direction so as to correspond to each of the four air holes 69, for example (see FIG. 6). The air filter 71 is made of a material that allows air to pass through and blocks water.

According to the above-described configuration, since the change in the internal pressure when the linear scale 65 moves to one side and the another side in the Z-axis direction with respect to the detection unit 67 can be suppressed, the occurrence of viscous resistance can be suppressed. Further, the air filter 71 can prevent dust or the like in the outer space from entering the interior of the case 63. Further, the electronic component mounting apparatus 1 including the linear head module 9 may be installed in a mist environment for preventing static electricity. In this case, if air containing moisture is allowed to enter the interior of the linear encoder 29, there is a possibility of causing corrosion of an electronic circuit. In the present embodiment, by using the air filter 71 which allows air to pass through and blocks water, invasion of moisture can be suppressed and corrosion of an electronic circuit can be suppressed.

### 8. Effects of the Embodiment

As described above, in the linear head module 9 of the present embodiment, the plurality of linear motors 23 is arranged such that the directions of the protruding portion 41a of the respective back yokes 41 are partially different. Thus, the orientation of the protruding portion 41a can be optimized so that the strength and vibration resistance of the linear head module 9 can be improved compared with, for example, the case where the protruding portion 41a of the back yokes 41 of all the linear motors 23 face in the same direction. As a result of the improvement in strength and vibration resistance, the frame 19, 21 can be reduced in size, so that the linear head module 9 can be reduced in size and weight.

Further, in the present embodiment, the plurality of linear motors 23 may be arranged such that the protruding portions 41a of the back yoke 41 at both ends in the X-axis direction face outward in the X-axis direction, and the protruding portions 41a of the back yoke 41 other than the protruding portions at both ends in the X-axis direction face outward in the Y-axis direction. In this case, the orientation of the protruding portion 41a can be optimized as compared with the case where the protruding portion 41a of all the back yokes 41 are arranged so as to face outward in the Y-axis direction, for example, and the protruding portion 41a facing outward in the X-axis direction function as ribs, so that the strength and vibration resistance of the linear head module 9 can be improved.

As described above, in the present embodiment, the strength and vibration resistance of the linear head module 9 can be improved by optimizing the direction of the protruding portion 41a of the back yoke 41. In response to this, the frame for supporting the plurality of linear motors 23 may be divided into a first frame 19 for supporting one side in the Z-axis direction and a second frame 21 for supporting the another side in the Z-axis direction spaced from the first frame 19. Thus, when the frame is divided, the linear head module 9 can be reduced in size and weight as compared with the case where the frame is integrated.

Further, in the present embodiment, a design value based on the ratio between the cross-sectional area of the back yoke 41 perpendicular to the Z-axis direction and the cross-sectional area of the magnet 39 perpendicular to the Z-axis direction may be set within a predetermined numerical range based on a simulation result. In this case, it is possible to optimize the part can be optimized, and the influence of the leakage of magnetic flux to the adjacent linear motor 23 can be reduced and the amount of magnet input can be maximized without separating the distance between the axes of the linear motor 23 and installing a magnetic shield. Therefore, the linear head module 9 can be reduced in size and weight.

Further, in the present embodiment, when the back yokes 41 of the adjacent linear motors 23 are disposed so as to be in contact with each other, the cross-sectional area of the magnet 39 perpendicular to the Z-axis direction may be approximately twice the cross-sectional area of the back yoke 41 perpendicular to the Z-axis direction. In this case, it is possible to reduce the influence of the leakage of the magnetic flux to the adjacent linear motor 23 and to maximize the input amount of the magnet without increasing the distance between the axes of the linear motor 23 and installing a magnetic shielding material. Therefore, the linear head module 9 can be reduced in size and weight.

Further, in the present embodiment, the foamed sheet 55 may be disposed between the inner peripheral surface of the back yoke 41 and the outer peripheral surface of the coil 43, and the volume of the foamed sheet 55 may be expanded by heat treatment to fix the coil 43 to the back yoke 41. In this case, since casting of the resin becomes unnecessary, man-hours can be greatly reduced, and manual work such as removal of the resin by a worker becomes unnecessary.

Further, in the present embodiment, the coil 43 may be hardened by varnish. In this case, the shape of the coil 43 can be prevented from being deformed when the volume of the foamed sheet 55 is expanded by the heat treatment.

Further, in the present embodiment, the fans 31A and 31B may be provided on one side and the another side in the Y-axis direction of the plurality of linear motors 23, and air may be blown from one side in the Y-axis direction to the plurality of linear motors 23 and air may be blown from the another side in the Y-axis direction. In this case, even when the gap between the respective linear motors 23 is narrow for miniaturization of the linear head module 9, air is blown to both surfaces of the plurality of linear motors 23 in the Y-axis direction, so that the linear motors 23 near the center in the X-axis direction can be cooled efficiently. Therefore, the cooling efficiency can be improved.

Further, in the present embodiment, the inner space S1 on one side in the Z-axis direction of the stator 35 may be communicated with the outer space of the back yoke 41 by the air hole 59 formed in the first linear motion guide portion 25, and the inner space S2 on the another side in the Z-axis direction of the stator 35 may be communicated with the outer space of the back yoke 41 by the air hole 61 formed in the second linear motion guide portion 27. In this case, since the change in the internal pressure when the movable element 33 moves to one side and the another side in the Z-axis direction with respect to the stator 35 can be suppressed, the generation of viscous resistance can be suppressed.

Further, in the present embodiment, an air hole 69 may be formed in the case 63 of the linear encoder 29, and the air filter 71 may be provided in the air hole 69. In this case, since the inner space S3 of the case 63 can be communicated with the outer space by the air hole 69, a change in the internal pressure when the linear scale 65 moves to one side and the another side in the Z-axis direction with respect to the detection unit 67 can be suppressed, and generation of viscous resistance can be suppressed. Further, the air filter 71 can prevent dust or the like in the outer space from entering the interior of the case 63.

In the present embodiment, an air filter made of a material that allows air to pass through and blocks water may be used as the air filter 71. In this case, even when the electronic component mounting apparatus 1 provided with the linear head module 9 is installed in a mist environment for preventing static electricity, for example, invasion of moisture can be suppressed and corrosion of an electronic circuit can be suppressed.

In the above description, when there is a description of “vertical”, “parallel”, “plane” or the like, the description does not have a strict meaning. The terms “vertical,” “parallel,” and “plane” mean “substantially vertical,” “substantially parallel,” and “substantially plane”, where design and manufacturing tolerances and errors are allowed.

In the above description, when there is a description such as “same”, “similar”, “equal to”, or “different” in the dimension, size, shape, position, etc. on the appearance, the description does not have a strict meaning. The terms “same,” “similar,” “equal to,” and “different” mean “substantially same,” “substantially similar,” “substantially equal to,” and “substantially different from,” in which design and manufacturing tolerances and errors are allowed.

In addition to the above-described methods, methods according to the above-described embodiments and modifications may be appropriately combined and used. In addition, although not shown by any example, various modifications are added to the above-described embodiments and modifications without departing from the spirit thereof.

The problems and effects to be solved by the above-described embodiments and modifications are not limited to the above-described contents. According to embodiments, modifications, and the like, it is possible to solve problems not described above or achieve effects not described above, and it is possible to solve only a part of the described problems or achieve only a part of the described effects.

What is claimed is:

1. A linear head module comprising:
a plurality of linear motors, each of the plurality of linear motors comprising:
a movable element comprising:
a shaft having a shaft axis and an outer peripheral surface around the shaft axis; and
a plurality of magnets fixed to the outer peripheral surface of the shaft; and
a stator comprising:
a back yoke which has a back yoke axis and an inner peripheral surface around the back yoke axis and in which the movable element is inserted to be movable along the shaft axis such that the shaft axis substantially coincides with the back yoke axis, the back yoke including a protruding portion that protrudes outwardly and that extends along the back yoke axis; and
a coil fixed to the inner peripheral surface of the back yoke to face the plurality of magnets with a gap between the coil and the plurality of magnets; and
the plurality of linear motors being arranged in a lattice shape such that the shaft axis of each of the plurality of linear motors is substantially parallel each other, the plurality of linear motors being arranged such that the protruding portion of a first linear motor among the plurality of linear motors protrudes along a first protruding direction different from a second protruding direction along which the protruding portion of a second linear motor among the plurality of linear motors protrudes.

2. The linear head module according to claim 1,
wherein the plurality of linear motors is arranged such that a first number of first direction linear motors arranged in a first direction perpendicular to the shaft axis is less than a second number of second direction linear motors arranged in a second direction perpendicular to the shaft axis and the first direction,
wherein the protruding portion of a third linear motor positioned at one end in the second direction among the second direction linear motors protrudes in the first protruding direction along the second direction, the protruding portion of a fourth linear motor positioned at another end opposite to the one end in the second direction among the second direction linear motors protrudes in the second protruding direction along the second direction, the first protruding direction being away from the another end, the second protruding direction being away from the one end, and
wherein the protruding portion of a fifth linear motor positioned between the third linear motor and the fourth linear motor among the second direction linear motors protrudes outward in a third protruding direction along the first direction.

3. The linear head module according to claim 1, further comprising:
a first frame connected to a base and supporting one side of the plurality of linear motors along the shaft axis; and
a second frame connected to the base opposite to the first frame and supporting another side of the plurality of linear motors along the shaft axis.

4. The linear head module according to claim 1, wherein a design value based on a ratio Ra of a cross-sectional area of the back yoke perpendicular to the shaft axis to a cross-sectional area of the plurality of magnets perpendicular to the shaft axis is within a predetermined numerical range.

5. The linear head module according to claim 4, wherein the cross-sectional area of the plurality of magnets is substantially twice the cross-sectional area of the back yoke.

6. The linear head module according to claim 1, wherein the stator includes a foamed sheet which is provided between the inner peripheral surface of the back yoke and an outer peripheral surface of the coil and which is configured to expand with heat treatment.

7. The linear head module according to claim 6, wherein the coil is hardened with varnish.

8. The linear head module according to claim 1,
wherein the plurality of linear motors is arranged adjacent to each other in a lattice pattern such that the number of columns in a first direction perpendicular to the axial direction is a first number and the number of columns in a second direction perpendicular to the axial direction and the first direction is a second number larger than the first number, and
wherein the linear head module further comprises
a first fan provided on one side of the plurality of linear motors in the first direction and configured to blow air to the plurality of linear motors from the one side, and
a second fan provided on another side opposite to the one side in the first direction and configured to blow air to the plurality of linear motors from the another side.

9. The linear head module according to claim 1, further comprising:
a first member provided on one side of the plurality of linear motors along the shaft axis and having an air hole communicating an inner space on one side of the stator along the shaft axis with an outer space of the back yoke with respect to each of the plurality of linear motors; and
a second member provided on another side opposite to the one side of the plurality of linear motors along the shaft axis and having an air hole communicating an inner space on another side of the stator along the shaft axis with the outer space of the back yoke with respect to each of the plurality of linear motors.

10. The linear head module according to claim 9, further comprising:
a linear encoder configured to detect a position of the movable element in each of the plurality of linear motors,
wherein the linear encoder comprises
a case having an air hole communicating the inner space with the outer space, and
an air filter provided in the air hole.

11. The linear head module according to claim 10, wherein the air filter configured to allow air to pass through and configured to block water.

12. An electronic component mounting apparatus comprising:
a linear head module according to claim 1;
a transport mechanism configured to transfer a substrate; and
a moving mechanism configured to move the linear head module with respect to the substrate, the linear head module standing on a base.
